(19) United States
(12) Patent Application Publication
(10) Pub. No.: US 2011/0038214 A1
(43) Pub. Date: Feb. 17, 2011

(54) GATE-SEPARATED TYPE FLASH MEMORY WITH SHARED WORD LINE

(75) Inventor: Jing Gu, Shanghai (CN)

Correspondence Address: ROSENBERG, KLEIN & LEE, 3458 ELLICOTT CENTER DRIVE-SUITE 101, ELLICOTT CITY, MD, 21043, US

(73) Assignee: GRACE SEMICONDUCTOR MANUFACTURING CORP., SHANGHAI 201203 (CN)

(21) Appl. No.: 12/988,852

(22) PCT Filed: May 13, 2009
(86) PCT No.: PCT/CN2009/071774

§ 371 Date: Oct. 21, 2010

(30) Foreign Application Priority Data
Dec. 30, 2008 (CN) 200810204971.2

(51) Int. Cl. G11C 16/04

(52) U.S. Cl. 365/185.18

(57) ABSTRACT

A gate-separated type flash memory with a shared word line includes: a semiconductor substrate, on which a source electrode area and a drain electrode area are separately arranged; a word line, which is arranged between the source electrode area and the drain electrode area; a first storage bit unit, which is arranged between the word line and the source electrode area, and a second storage bit unit, which is arranged between the word line and the drain electrode area. The two storage bit units and word line are separated by a tunneling oxide layer. The two storage bit units respectively have a first control gate, a first floating gate and a second control gate, a second floating gate, and the two control gates are separately respectively arranged on two floating gates.

### BACKGROUND OF THE INVENTION

1. Field of the Invention

The present invention relates to semiconductor design and manufacturing technology, and in particular to a gate-separated type flash memory with a shared word line.

2. The Prior Arts

In recent years, flash memory has become a hot topic in the research and development of non-volatile memory due to its various advantages of fast speed, high storage density, and performance reliability. Since the advent of the first flash memory device in 1980's, flash memory has been utilized extensively in mobile and communication devices, such as mobile phones, notebook computers, personal data assistants (PDA), and USB disks (portable disk), etc. Flash memory is a type of non-volatile memory that stores data by controlling the turn-on/turn-off of a gate electrode in a circuit by changing the threshold voltage of a transistor or a storage unit. The data stored in memory will not be lost or disappear due to a power outage. Flash memory is a special type of read-only-memory (ROM) that can be an electrically erasable programmable read-only memory (EEPROM). Presently, flash memory has occupied a major share of the market of non-volatile semiconductor memory and has become one of the non-volatile semiconductor memories capable of achieving the fastest technical progress and development.

However, while the existing flash memory is aimed at achieving higher storage density, it is rather limited by the programming voltage utilized in the manufacturing process. Therefore, the demand for higher storage density flash memory has been a major driving force for the research and development of flash memory technology. In striving for higher storage density of conventional flash memory, the effort to realize further reduction of programming voltage of a memory device has met with tremendous challenge due to structure limitations.

In general, the structure of flash memory can be classified into a separated gate structure, a stacked gate structure, or a combination of the two. Due to the special structure of a separated gate flash memory, its unique superiority in functions and performance can be fully realized while executing data programming and erasing. Since the separated gate flash memory has the advantage of high programming efficiency, and its word line structure can avoid the over-erasure problem, such that it can be utilized in a wide variety of applications. However, since a separated gate flash memory has one additional word line as compared with a stacked gate flash memory, such that its chip area is increased. Therefore, the problem as to how to raise the functions of a chip while reducing its size has to be solved urgently.

### SUMMARY OF THE INVENTION

In order to overcome the shortcomings and problems of the prior art, the present invention discloses a gate-separated type flash memory with a shared word line that is capable of effectively reducing the area of a chip and avoiding problems of over-erasure while keeping the electric isolation of a chip unchanged.

In order to achieve the above-mentioned objective and more, the present invention discloses a gate-separated type flash memory with a shared word line comprising: a semiconductor substrate having source electrode area and drain electrode area disposed thereon and spaced apart, a word line disposed between the source electrode area and the drain electrode area, a first storage bit unit provided between the word line and the source electrode area, a second storage bit unit provided between the word line and the drain electrode area. A tunnel oxide layer separates the two storage bit units and the word line. The two storage bit units are each provided respectively with a first control gate, a first floating gate, a second control gate, and a second floating gate. The two control gates are disposed respectively on the two floating gates and are spaced apart.

According to one aspect of the present invention, the two control gates are polysilicon control gates, the two floating gates are polysilicon floating gates, and the word-line is a polysilicon selection gate.

According to another aspect of the present invention, the tunnel oxide layer is a silicon oxide layer, a silicon nitride layer, or their combinations.

According to yet another aspect of the present invention, various first storage bit unit read voltages are applied on the word line, the first control gate, the second control gate, the source electrode area, and the drain electrode area respectively, thus realizing a read operation of a first storage bit unit.

According to another aspect of the present invention, various first storage bit unit read voltages such as 2.5V, 2.5V, 4V, 0V, and 2V are applied on the word line, the first control gate, the second control gate, the source electrode area, and the drain electrode area respectively, thus realizing a read operation of a first storage bit unit.

According to yet another aspect of the present invention, various second storage bit unit read voltages are applied on the word line, the first control gate, the second control gate, the source electrode area, and the drain electrode area respectively, thus realizing a read operation of a second storage bit unit.

According to another aspect of the present invention, various second storage bit unit read voltages such as 2.5V, 4V, 2.5V, 2V, and 0V are applied on the word line, the first control gate, the second control gate, the source electrode area, and the drain electrode area respectively, thus realizing a read operation of a second storage bit unit.

According to still another aspect of the present invention, various first storage bit unit programming voltages are applied on the word line, the first control gate, the second control gate, the source electrode area, and the drain electrode area respectively, thus realizing a programming operation of a first storage bit unit.

According to another aspect of the present invention, various first storage bit unit programming voltages such as 1.5V, 10V, 4V, 5V, and 0V are applied on the word line, the first control gate, the second control gate, the source electrode area, and the drain electrode area respectively, thus realizing a programming operation of a first storage bit unit.

According to yet another aspect of the present invention, various second storage bit unit programming voltages are applied on the word line, the first control gate, the second control gate, the source electrode area, and the drain electrode area respectively, thus realizing a programming operation of a second storage bit unit.

According to another aspect of the present invention, various second storage bit unit programming voltages such as 1.5V, 4V, 10V, 0V and 5V are applied on the word line, the first control gate, the second control gate, the source electrode area, and the drain electrode area respectively, thus realizing a programming operation of a second storage bit unit.

According to still another aspect of the present invention, various storage bit unit erasure voltages are applied on the word line, the first control gate, the second control gate, the source electrode area, and the drain electrode area respectively, thus realizing erasure operations of the first storage bit unit and the second storage bit unit.

According to another aspect of the present invention, various storage bit unit erasure voltages such as 11V, 0V, 0V, 0V and 0V are applied on the word line, the first control gate, the second control gate, the source electrode area, and the drain electrode area respectively, thus realizing erasure operations of the first storage bit unit and the second storage bit unit.

In the present invention, a gate-separated type flash memory with a shared word line is disclosed, wherein two storage bit units share a word line and the reading, programming, and erasing of a storage bit unit are realized through applying various operating voltages on the word line, two control gates, source electrode area, and the drain electrode area. In this way, a word line sharing structure is utilized, so that Separated-Gate Flash Memory is capable of effectively reducing the area of a chip and avoiding the problem of over-erasure while keeping the electrical isolation property of the chip unchanged.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawing in connection with the detailed description of the present invention to be made later are described briefly as follows, in which:

FIG. 1 is a schematic diagram of a gate-separated type flash memory with a shared word line according to an embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

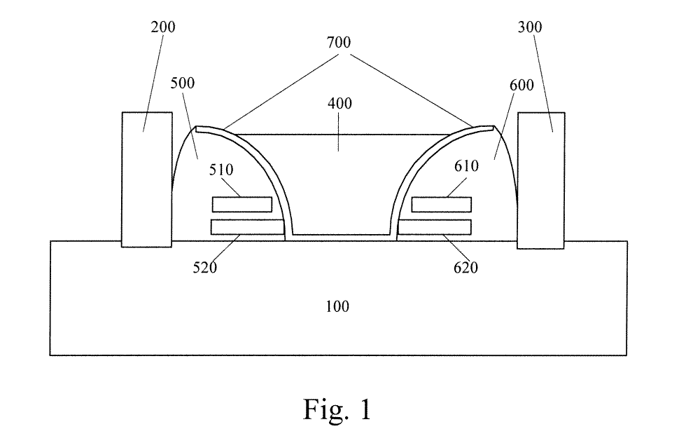

Refer to FIG. 1, for a schematic diagram of a gate-separated type flash memory with a shared word line according to an embodiment of the present invention. As shown in FIG. 1, a gate-separated type flash memory with a shared word line comprises a semiconductor substrate 100 having a source electrode area 200 and a drain electrode area 300 disposed thereon and spaced apart; a word line 400 disposed between the source electrode area 200 and the drain electrode area 300; a first storage bit unit 500 provided between the word line 400 and the source electrode area 200; and a second storage bit unit 600 provided between the word line 400 and the drain electrode area 300. A tunnel oxide layer 700 separates the two storage bit units 500, 600, the word line 400. The two storage bit units 500 and 600 are each provided respectively with a first control gate 510, a first floating gate 520, a second control gate 610, and a second floating gate 620. The two control gates 510 and 520 are disposed on the two floating gates 610 and 620 respectively and are spaced apart.

According to a preferred embodiment of the present invention, the two control gates 510, 520 are polysilicon control gates, the two floating gates 610 and 620 are polysilicon floating gates, and the word line 400 is a polysilicon selection gate. The tunnel oxide layer 700 is a silicon oxide layer, a silicon nitride layer, or a layer of the combination of the two.

In the present invention, the reading, programming, and erasing operations of storage bit units 500 and 600 are realized through applying various operating voltages on the word line 400, two control gates 510 and 520, the source electrode area 200, and the drain electrode area 300 respectively.

According to a preferred embodiment of the present invention, various first storage bit unit read voltages such as 2.5V, 2.5V, 4V, 0V, and 2V are applied on the word line 400, the first control gate 510, the second control gate 520, the source electrode area 200, and the drain electrode area 300 respectively, thus realizing a read operation of a first storage bit unit 500.

In the present invention, various second storage bit unit read voltages such as 2.5V, 4V, 2.5V, 2V, and 0V are applied on the word line 400, the first control gate 510, the second control gate 520, the source electrode area 200, and the drain electrode area 300 respectively, thus realizing a read operation of a second storage bit unit 600.

In a preferred embodiment of the present invention, current exists in a channel flowing from the source electrode area 200 to the drain electrode area 300, such that the existence or non-existence of charges in polysilicon floating gates 520 and 620 will affect the magnitude of the channel current. When charges exist in floating gates 520 and 620, the channel current is very small; and when no charges exist in floating gates 520 and 620, the channel current is relatively large. Supposing that the state of small current in channel is set to “0” ,while the state of large current in channel is set to “1”, a charge-storage or a charge-non-storage state of floating gates 520 and 620 can be classified and designated as corresponding to “0” or “1” data storage state. In this way, data storage/read functions of storage bit units 500 and 600 can be realized.

According to a preferred embodiment of the present invention, various first storage bit unit programming voltages such as 1.5V, 10V, 4V, 5V, and 0V are applied on the word line 400, the first control gate 510, the second control gate 520, the source electrode area 200, and the drain electrode area 300 respectively, thus realizing a programming operation of a first storage bit unit 500.

In a preferred embodiment of the present invention various second storage bit unit programming voltages such as 1.5V, 4V, 10V, 0V, and 5V are applied on the word line 400, the first control gate 510, the second control gate 520, the source electrode area 200, and the drain electrode area 300 respectively, thus realizing a programming operation of a second storage bit unit 600.

When voltage difference between a source electrode and a drain electrode is large enough, some of the high energy electrons will pass through an insulation dielectric layer and enter into a floating gate on the insulation dielectric layer. This phenomenon is referred to as hot electron injection. The insulation dielectric layer is made of oxide of silicon or nitride of silicon, such as silicon dioxide or silicon nitride. In a preferred embodiment of the present invention, upon applying a read operation voltage, electrons in a channel will flow from a drain electrode area 200 to a source electrode area 300, and a part of the electrons will be injected into silicon floating gates 520 and 620 of nm size through hot electron injection, thereby realizing programming operations of storage bit units 500 and 600.

According to a preferred embodiment of the present invention, various storage bit unit erasure voltages such as 11V, 0V, 0V, 0V and 0V are applied on the word line 400, the first control gate 510, the second control gate 520, the source electrode area 200, and the drain electrode area 300 respectively, thus realizing a erasure operation of a first storage bit unit 500 and a second storage bit unit 600. Upon applying an erasure operation voltage, the electrons stored in the floating gates 520 and 620 will be Fowler-Nordheim (FN) tunneled to the word line 400 under a strong electric field, and then leaked out through the word line 400, thus realizing erasure operations of storage bit units 500 and 600.

In the present invention, a gate-separated type flash memory with a shared word line is disclosed, wherein two storage bit units share a word line, and the reading, programming, and erasing of storage bit units are realized through applied various operating voltages on the word line, two control gates, source electrode area, and drain electrode area. In this way, a word line sharing structure is utilized so that gate-separated type flash memory is capable of effectively reducing the area of a chip and avoiding the problem of over-erasure, while keeping the electrical isolation property of the chip unchanged.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

1. A gate-separated type flash memory with a shared word line, comprising:
a semiconductor substrate, having a source electrode area and a drain electrode area disposed thereon and spaced apart;
a word line, disposed between said source electrode area and said drain electrode area;
a first storage bit unit, provided between said word line and said source electrode area;
a second storage bit unit, provided between said word line and said drain electrode area;
wherein a tunnel oxide layer separates said two storage bit units and said word line, said two storage bit units are each provided respectively with a first control gate, a first floating gate, a second control gate, and a second floating gate, and said two control gates are disposed on said two floating gates respectively and are spaced apart.

2. The gate-separated type flash memory with a shared word line as claimed in claim 1, wherein said two control gates are polysilicon control gates, said two floating gates are polysilicon floating gates, and said word-line is a polysilicon selection gate.

3. The gate-separated type flash memory with a shared word line as claimed in claim 1, wherein said tunnel oxide layer is a silicon oxide layer, a silicon nitride layer, or a combination of said two layers.

4. The gate-separated type flash memory with a shared word line as claimed in claim 1, wherein various first storage bit unit read voltages are applied on said word line, said first control gate, said second control gate, said source electrode area, and said drain electrode area respectively in performing a read operation of said first storage bit unit.

5. The gate-separated type flash memory with a shared word line as claimed in claim 4, wherein said various first storage bit unit read voltages of 2.5V, 0V, 4V, 0V, and 1V are applied on said word line, said first control gate, said second control gate, said source electrode area, and said drain electrode area respectively in performing a read operation of said first storage bit unit.

6. The gate-separated type flash memory with a shared word line as claimed in claim 1, wherein various second storage bit unit read voltages are applied on said word line, said first control gate, said second control gate, said source electrode area, and said drain electrode area respectively in performing a read operation of said second storage bit unit.

7. The gate-separated type flash memory with a shared word line as claimed in claim 6, wherein various second storage bit unit read voltages of 2.5V, 4V, 0V, 1V, and 0V are applied on said word line, said first control gate, said second control gate, said source electrode area, and said drain electrode area respectively in performing a read operation of said second storage bit unit.

8. The gate-separated type flash memory with a shared word line as claimed in claim 1, wherein various first storage bit unit programming voltages are applied on said word line, said first control gate, said second control gate, said source electrode area, and said drain electrode area respectively in performing a programming operation of said first storage bit unit.

9. The gate-separated type flash memory with a shared word line as claimed in claim 8, wherein various first storage bit unit programming voltages of 1.5V, 10V, 4V, 5V, and 0V are applied on said word line, said first control gate, said second control gate, said source electrode area, and said drain electrode area respectively in performing a programming operation of said first storage bit unit.

10. The gate-separated type flash memory with a shared word line as claimed in claim 1, wherein various second storage bit unit programming voltages are applied on said word line, said first control gate, said second control gate, said source electrode area, and said drain electrode area respectively in performing a programming operation of said second storage bit unit.

11. The gate-separated type flash memory with a shared word line as claimed in claim 10, wherein various second storage bit unit programming voltages of 1.5V, 4V, 10V, 0V and 5V are applied on said word line, said first control gate, said second control gate, said source electrode area, and said drain electrode area respectively in performing a programming operation of said second storage bit unit.

12. The gate-separated type flash memory with a shared word line as claimed in claim 1, wherein various storage bit unit erasure voltages are applied on said word line, said first control gate, said second control gate, said source electrode area, and said drain electrode area respectively in performing erasure operations of said first storage bit unit and said second storage bit unit.

13. The gate-separated type flash memory with a shared word line as claimed in claim 12, wherein various storage bit unit erasure voltages of 11V, 0V, 0V, 0V and 0V are applied on said word line, said first control gate, said second control gate, said source electrode area, and said drain electrode area respectively in performing erasure operations of said first storage bit unit and said second storage bit unit.
